(19) United States
(12) Patent Application Publication
(10) Pub. No.: US 2026/0031143 A1
(43) Pub. Date: Jan. 29, 2026

(54) SYSTEM AND METHOD FOR REDUCTION OF TIME-DEPENDENT DIELECTRIC BREAKDOWN (TDDB) OF UNSELECTED TRANSISTORS OF A RESISTIVE RANDOM-ACCESS MEMORY (RERAM) DEVICE

(71) Applicant: Weebit Nano Ltd., Hod Hasharon (IL)

(72) Inventor: Ishai NAVEH, Clearwater, FL (US)

(73) Assignee: Weebit Nano Ltd., Hod Hasharon (IL)

(21) Appl. No.: 19/270,645

(22) Filed: Jul. 16, 2025

Related U.S. Application Data
(60) Provisional application No. 63/674,441, filed on Jul. 23, 2024.

(51) Int. Cl. G11C 13/00

(52) U.S. Cl. CPC G11C 13/0069; G11C 13/0026; G11C 13/0028; G11C 13/003; G11C 13/0097; G11C 2213/79

(57) ABSTRACT

During traditional programming of resistive random-access memory (ReRAM) arrays, many ReRAM cells are unnecessarily stressed. As a result of the overstress, the time dependent dielectric breakdown (TDDB) is low. According to an embodiment, negative voltages are used on the bit-line (BL) of the cell being programmed and on the and on all word-line (WL) of cells that are not being programmed. By doing so, it is possible to use a lower WL voltage and a lower source line (SL) voltage than is used in currently implemented solutions. As a result, stress on non-selected cells, and in particular transistors of non-selected cells, is reduced, thereby reducing TDDB.

### CROSS-REFERENCE TO RELATED APPLICATIONS

This application claims the benefit of U.S. Provisional Application No. 63/674,441 filed on Jul. 23, 2024, the contents of which are hereby incorporated by reference.

### TECHNICAL FIELD

The present disclosure generally relates to resistive random-access memory (ReRAM) cells, and more particularly to the reduction of the impact of time-delayed dielectric breakdown in ReRAM cells.

### BACKGROUND

The time-dependent dielectric breakdown (TDDB), which is sometimes also referred to as time-delayed dielectric breakdown, is an issue that impacts semiconductor devices that rely on dielectric materials. A complementary metal oxide semiconductor (CMOS) integrated circuit (IC) may be affected by TDDB as the insulation properties of gate oxides in CMOS transistors, typically field effect transistors (FETs) of the IC deteriorate over time. Gate oxide breaks down due to TDDB, which can lead to electrical leakage and impact the operation of the transistor, potentially causing circuit failure. Similarly, the TDDB may impact performance or cause failure of power electronics and microelectromechanical systems (MEMs).

An example of a non-volatile memory (NVM) is the resistive random-access memory (ReRAM). ReRAM is known for its potential to provide high-density, fast, and energy-efficient data storage. It operates by exploiting the resistance switching properties of certain dielectric materials, that are used in its resistive element. It further comprises a transfer transistor to which the resistive element is connected to and controlled for its various operations. At programming, the transistor and the resistive element of the cell being programmed experience dielectric stress as a result of the application of voltage. It may be desirable to integrate such NVM into designs that are logic designs and which employ manufacturing technologies that have transistors that typically are not designed to sustain extended stress.

One of ordinary skill in the art would therefore readily appreciate the need to manage TDDB to ensure the endurance, performance, and/or data retention capabilities of semiconductor devices. While various strategies to mitigate TDDB in ReRAM devices, for example, optimizing the dielectric material properties, voltage pulse shaping, and implementing error correction codes (ECC) to mitigate the impact of potential data errors resulting from dielectric breakdown. However, this addresses mainly those cells being programmed.

FIG. 1 shows a schematic block diagram 100 of a resistive random-access memory (ReRAM) device. The device comprises a ReRAM array 110 that is organized in rows and columns of ReRAM cells. Bit line (BL) and source line (SL) control unit 120 and word line (WL) control unit 130 provide the signals for SET, RESET, and read of the ReRAM cells, under the control of the control logic unit 140.

FIG. 2 is a schematic diagram of a ReRAM array 110 of the ReRAM device 100 shown in FIG. 1 using standard operational voltages. Each ReRAM cell comprises an access transistor 250 and a resistance 240. In this particular case, the ReRAM cell i,j, i.e., the ReRAM cell that comprises the resistance 240-i,j and the access transistor 250-i,j, is selected for programming as WLⱼ 230-j is at 2V and SLᵢ 220-i is at 1.8V. In this case the row i access transistors 250-i,1, 250-i,1, all the way to access transistor 250-n,j, but for access transistor 250-i,j, experience a leakage current, which may become significant in the case of even not very large arrays, where a large number of access transistors may be leaking.

The higher voltages used, especially at RESET of the ReRAM cell, stress the column j access transistors 250-1,j, 250-2,j, all the way to access transistor 250-i,m, resulting in a need to use larger transistors of the process technology in order to withstand the stress. A small core transistor would breakdown reducing device reliability. While the Vas voltage stress on the access transistor 250-i,j is within limits, there are many more, in fact, as this figure shows, m−1 access transistors 250 that experience a higher stress. For example, the access transistor 250-i,1 experiences a voltage drop between SLᵢ=1.8V 220-i and BLᵢ=0V 210-i. Hence, many more bits suffer the stress impact. Use of higher voltage bearing transistors means that the area of the cell is significantly impacted by the size of the access transistor, for example access transistor 250-i,j.

It would therefore be advantageous to provide a solution that overcomes the deficiencies of the current implementations by providing less stress on non-selected access transistors 250 and in particular the use of high voltage transistors instead as the core transistors of the process. It would be further advantageous to provide a solution that will enable the use of core transistors of the process, rather than transistors that are designed to withstand higher voltage stress. It would be further necessary to overcome certain operative deficiencies of a core transistor when operating the higher voltages. This is particularly important when considering that both selected and unselected access transistors 250 may experience the higher voltage at different phases of reading and/or writing the ReRAM cell.

### SUMMARY

A summary of several example embodiments of the disclosure follows. This summary is provided for the convenience of the reader to provide a basic understanding of such embodiments and does not wholly define the breadth of the disclosure. This summary is not an extensive overview of all contemplated embodiments, and is intended to neither identify key or critical elements of all embodiments nor to delineate the scope of any or all aspects. Its sole purpose is to present some concepts of one or more embodiments in a simplified form as a prelude to the more detailed description that is presented later. For convenience, the term “some embodiments” or “certain embodiments” may be used herein to refer to a single embodiment or multiple embodiments of the disclosure.

Certain embodiments disclosed herein include a resistive random-access memory (ReRAM) device having improved time-dependent dielectric breakdown (TDDB) comprising: an array of ReRAM cells arranged in a plurality of columns and a plurality of rows, each cell comprising a resistive element having a first port and a second port and a select transistor having a gate port, a drain port and a source port, wherein the second port of the resistive element is electrically connected to the drain port of the select transistor; a plurality of word lines, each word line designated to a column of the plurality of columns and electrically connecting to each gate of a select transistor of each ReRAM cell of the column; a plurality of bit lines, each bit line designated to a row of the plurality of rows and electrically connecting to a first port of each resistive element of each ReRAM cell of the row; a plurality of source lines, each source line designated to the row of the plurality of rows and electrically connecting to a source port of each select transistor of each ReRAM cell of the row; a word line control unit (WLCU) electrically connect to each of the plurality of word lines; a bit line and source line control (BLSLCU) unit electrically connected to each of the plurality of bit lines and each of the plurality of source lines; and a control unit electrically connected to the BLSLCU and configured to provide a first negative voltage to a bit line of the plurality of rows at a RESET programming of a first ReRAM cell which includes the first ReRAM cell.

Certain embodiments disclosed herein also include a method for performing a RESET programming of a resistive random-access memory (ReRAM) device having improved time-dependent dielectric breakdown (TDDB), the method comprising: selecting, by a bit line and source line control unit (BLSLCU) of the ReRAM device, one or more rows and, by a word line control unit (WLCU) of the ReRAM device, one or more columns of a ReRAM array of the ReRAM device, where intersecting selected columns and selected rows indicate that a ReRAM cell to be RESET, and wherein the indicated ReRAM cell is a selected ReRAM cell; applying, by the WLCU, a first voltage to each word line of the ReRAM array of non-selected columns; applying, by the WLCU, a first positive voltage to each word line of the ReRAM array of the selected columns; applying, by the BLSLCU, a reference voltage to bit lines of non-selected rows; applying, by the BLSLCU, a reference voltage to source lines of the non-selected rows; applying, by the BLSLCU, a second negative voltage to bit lines of the selected rows; and applying, by the BLSLCU, a second positive voltage to source lines of the selected rows; wherein applying of the voltages cause the RESET of each of the selected ReRAM cells without overstressing select transistors of non-selected ReRAM cells.

### BRIEF DESCRIPTION OF THE DRAWINGS

The subject matter disclosed herein is particularly pointed out and distinctly claimed in the claims at the conclusion of the specification. The foregoing and other objects, features, and advantages of the disclosed embodiments will be apparent from the following detailed description taken in conjunction with the accompanying drawings.

FIG. 1 is a schematic block diagram of a resistive random-access memory (ReRAM) device.

FIG. 2 is a schematic diagram of a ReRAM array of the ReRAM device shown in FIG. 1 using standard operational voltages.

FIG. 3 is a first schematic diagram of a ReRAM array of a ReRAM device using operational voltages according to an embodiment.

FIG. 4 is a second schematic diagram of a portion of a ReRAM array of a ReRAM device using principle of operational voltages according to an embodiment.

FIG. 5 is a third schematic diagram of a portion of a ReRAM array of a ReRAM device using principle of operational voltages according to an embodiment.

FIG. 6 is a graph depicting time-dependent dielectric breakdown (TDDB) gains according to an embodiment.

FIG. 7 is a flowchart describing RESET programming of a ReRAM array according to an embodiment.

FIG. 8 is a flowchart describing RESET programming of a ReRAM array according to another embodiment.

### DETAILED DESCRIPTION

It is important to note that the embodiments disclosed herein are only examples of the many advantageous uses of the innovative teachings herein. In general, statements made in the specification of the present application do not necessarily limit any of the various claims. Moreover, some statements may apply to some inventive features but not to others. In general, unless otherwise indicated, singular elements may be in plural and vice versa with no loss of generality. In the drawings, like numerals refer to like parts through several views.

During traditional programming of resistive random-access memory (ReRAM) arrays, many ReRAM cells (also referred to herein simply as cells) are unnecessarily stressed. As a result of the overstress, the time dependent dielectric breakdown (TDDB) is low. According to an embodiment, negative voltages are used on the bit-line (BL) of the cell being programmed and on the and on all word-line (WL) of cells that are not being programmed. By doing so, it is possible to use a lower WL voltage and a lower source line (SL) voltage than is used in conventional solutions. As a result, stress on non-selected cells, and in particular transistors of non-selected cells, is reduced, thereby reducing TDDB.

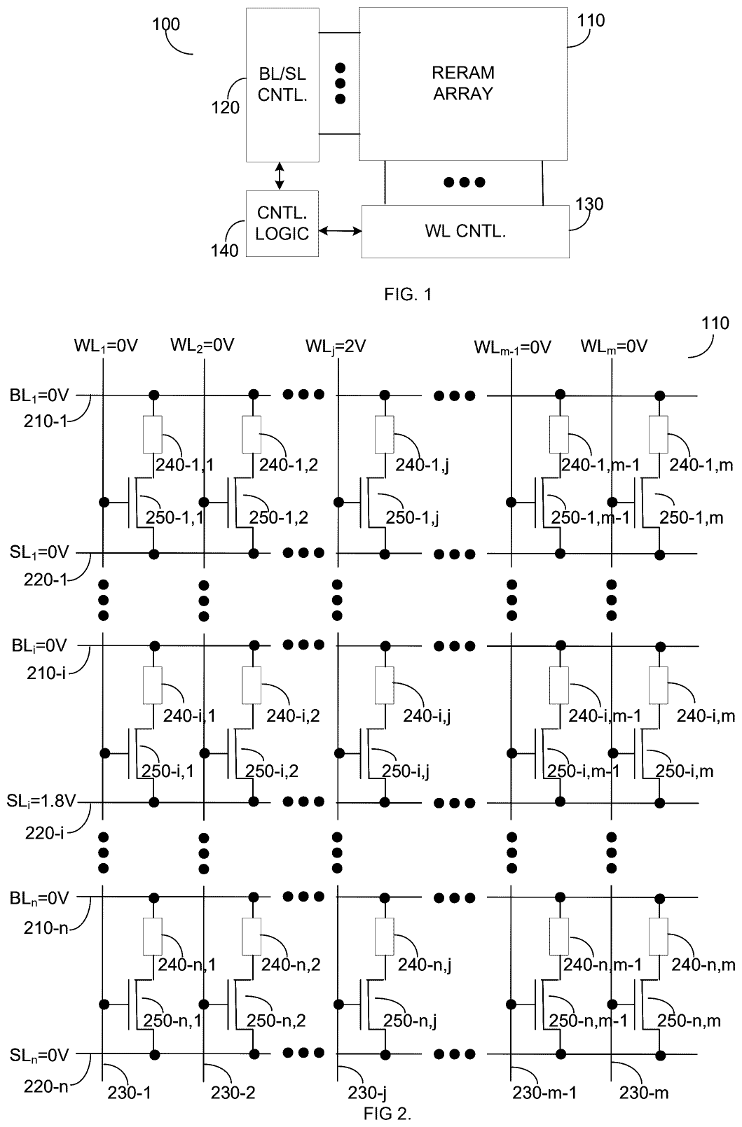

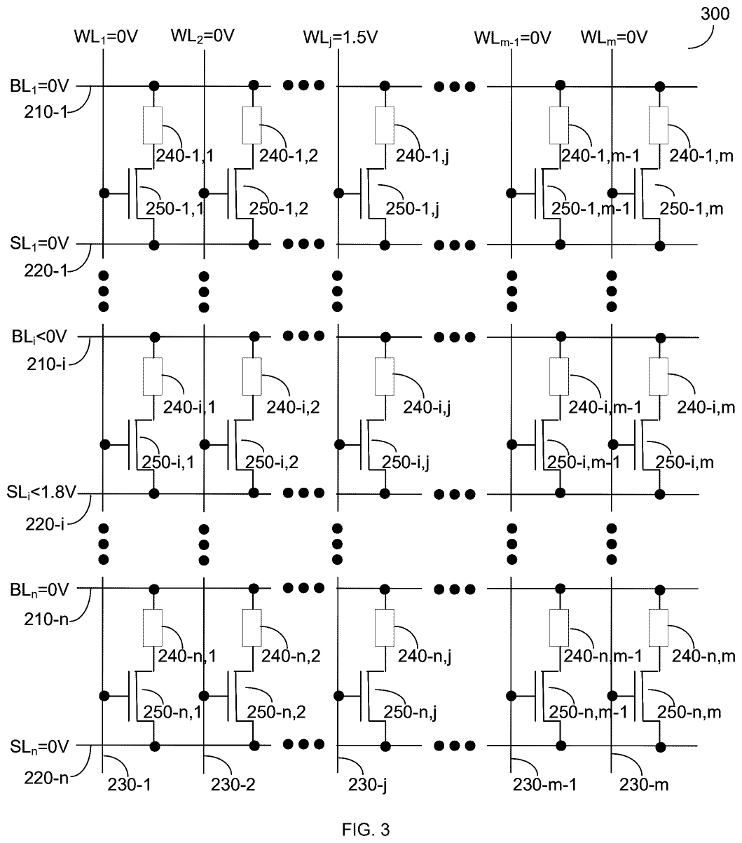

FIG. 3 is an example first schematic diagram of a first ReRAM array 300 of a ReRAM device shown in FIG. 1, using operational voltages according to an embodiment. The ReRAM device from a schematic point-of-view is similar to that shown in FIG. 1, however, the voltages supplied during RESET operation are different and are shown in FIG. 3. In this example, the ReRAM cell i,j is RESET. WL₁ 230-1 through WLₘ 230-m, but for WLⱼ 230-j, are at 0V, while WLⱼ 230-j is at 1.5V. This is lower by 0.5V when compared to the voltage supplied according to FIG. 2. BL₁ 210-1 through BLₙ 210-n, but for BLᵢ 210-i, are provided with 0V, while BLᵢ 210-i is provided with a voltage that is lower than 0V, i.e., lower than the voltage supplied to BLᵢ 210-i in the known implementations. In an embodiment BLᵢ 210-i is provided with a voltage of-250 mV (−0.25V). SL₁ 220-1 through SLₙ 220-n, but for SLᵢ 220-i, are provided with 0V, while SLᵢ 220-i is provided with a voltage that is lower than 1.8V, i.e., lower than the voltage supplied to SLᵢ 220-i in the known implementations. In an embodiment SLᵢ 220-i is provided with a voltage of 1.5V.

According to embodiments, for every 1 mV reduced below 0V of the BL voltage, a corresponding roughly 1 mV may be reduced from the WL voltage. For example, if the BL is at −200 mV then a reduction of 200 mV in the WL voltage may be applied, or, in an embodiment, between 195 mV and 205 mV; if the BL is at −250 mV then a reduction of 250 mV in the WL voltage may be applied, or, in an embodiment, between 240 mV and 260 mV.

As can be understood from the voltage scheme essentially the same voltages are supplied to the access transistor 250-i,j according to this embodiment, as were the voltages according to the current embodiment, but for the fact that BLᵢ operated using a negative voltage. The major difference is the voltage stress experienced by the non-selected access transistors 250, for example transistors 250-1,j through 250-n-j, but for access transistor 250-i,j which is to experience a RESET. While these non-selected access transistors 250 in the RESET column experience less voltage stress, leakage of the access transistors 250 in the RESET row, i.e, access transistors 250-i,1 through 250-i,m, but for the access transistor 250-i,j being RESET, maintain the low leakage current. One of ordinary skill in the art would therefore appreciate that in order to perform the teachings herein, at least the BL/SL control 120 is adapted to be enabled to provide a negative voltage when performing a RESET of a resistance 240. According to an embodiment, the leakage of all access transistors 250 that are unselected in bit line but have their respective BL 210 and SL 220 active should be no more than a predetermined percent value from the current of the selected access transistor. For example, but not by way of limitation, the leakage of all access transistors 250 that are unselected but have their respective BL 210 and SL 220 active should be no more than one percent (1%) of the current of the selected access transistor.

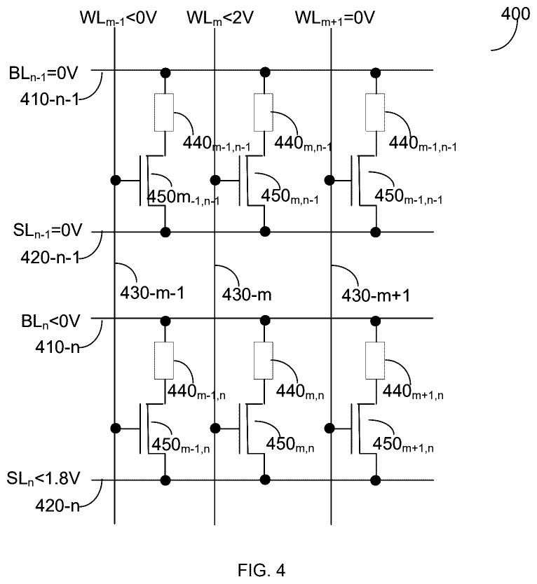

FIG. 4 is an example second schematic diagram of a portion of a ReRAM array 400 of a ReRAM device using principle of operational voltages according to an embodiment. The ReRAM array is arranged as an ‘I’ by ‘J’ array of ReRAM cells, where ‘I’ and ‘J’ are integers greater than ‘1’. The cell programmed is the one comprising of the resistive element 440_{m,n} and the select transistor 450_{m,n}. The values of ‘m’ and ‘n’ are within the ranges of ‘I’ and ‘J’, such that neither ‘m’ nor ‘n’ can be smaller than ‘2’ or larger than ‘I’ or ‘J’, respectively. In this case, for illustration purposes, the WLₘ₋₁ 430-m−1 receives a voltage lesser than 0V, i.e., a negative voltage (typically with respect to ground, or another common reference potential), while the WLₘ₊₁ 430-m+1 receives a voltage of 0V. The non-programmed resistive elements of row n−1, i.e., resistive elements 440_{m-1,n-1}, 440_{m,n-1}, and 440_{m+1,n-1}, receive BLₙ₋₁ 410-n−1 at 0V and SLₙ₋₁ 420-n−1 at 0V. The resistive elements of row n, i.e., resistive elements 440_{m-1,n}, 440_{m,n}, and 440_{m+1,n}, receive BLₙ₋₁ 410-n−1 that is below 0V, i.e., a negative voltage, and SLₙ₋₁ 420-n−1 is at a positive voltage of less than 1.8V. In order to program the resistive element WLₘ 430-m receives a positive voltage that is less than 2V, but not less than the voltage presented on SLₙ 420-n.

As a result of the application of the voltage scheme discussed above, which is as noted for illustration purposes only, the transistors 450_{m-1,n-1}, 450_{m,n-1}, and 450_{m+1,n-1}, do not present current leakage, as would be appreciated by one of skill in the art. Furthermore, no current leakage is present in transistor 450_{m-1,n}, as would also be appreciated by one of skill in the art. However, and that is what this example is out to illustrate, the transistor 450_{m+1,n} does have current leakage. Therefore, providing a negative bias to the word-lines of the non-selected cells suppresses leakage of such non-selected cells according to an embodiment. Hence, the negative biasing of WLₘ₋₁ 430-m−1 is advantageous over the 0V biasing suggested for WLₘ₊₁ 430-m+1. Therefore, according to embodiments, a negative bit-line voltage is applied during RESET, allowing to reach the same RESET voltage on the programmed ReRAM cell with a lower word-line voltage of the programmed cell. The embodiment further needs reducing the SL 420 voltage of the programmed cell to keep the same Vos on the selected transistor.

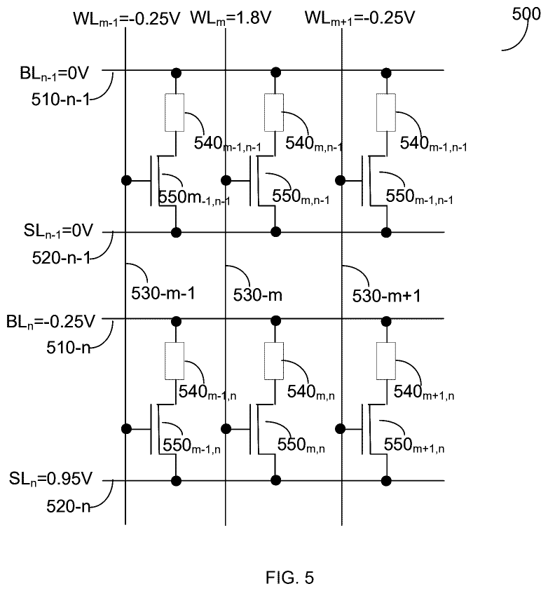

FIG. 5 is an example third schematic diagram of a portion of a ReRAM array 500 of a ReRAM device using principle of operational voltages according to an embodiment. In this diagram, specific programming voltage for the programming of the resistive element 540_{m,n} is shown, which provides the benefits of the disclosed embodiments to the ReRAM device. The voltages supplied to the non-selected cells are WLₘ₋₁=−0.25V 530-m−1, WLₘ₊₁=−0.25V 530-m+1, BLₙ₋₁=0V 510-n−1, and SLₙ₋₁=0V 520-n−1.

The non-selected row n−1 has all transistors 550_{m-1,n-1}, 550_{m,n-1}, and 550_{m+1,n-1}, without leakage current as explained in FIG. 4 for transistor 450_{m-1,n-1}, 450_{m,n-1}, and 450_{m+1,n-1}. Therefore, BLₙ₋₁ 510-n−1 and SLₙ₋₁ 520-n−1 are each biased at 0V. WLₘ₋₁ 530-m−1 and WLₘ₊₁ 530-m+1, that are the word lines for non-selected cells in columns m−1 and m+1, are each biased at −0.25V. In order to RESET the resistive element 540_{m,n} BLₙ 510-n is biased at −0.25V and SLₙ 520-n is biased at 1.55V. The gate voltage of the transistors of non-selected cells receives the −0.25V from the word lines of the non-selected cells in order to suppress bit line leakage of non-selected cells. Therefore, as shown in both FIGS. 4 and 5, the embodiment that uses negative voltages on the bit line of the selected cell may be implemented without degrading the current leakage performance of the ReRAM array.

In summary, according to the embodiments, the bit line voltage applied during RESET is negative, that enables reaching the same RESET voltage on the ReRAM with a lower word line voltage. The SL voltage is therefore also reduced in order to keep the same VDs on the selected transistor of the selected cell. The word line voltage of the non-selected cells, other than the word line that includes the selected cell, is biased at a negative value to suppress leakage of the non-selected cells. The word line voltage of the column of the cell being programmed is reduced from the typical 2V to 1.8V, achieving the same voltage for the selected cell during RESET as the bit line voltage is at −250 mV.

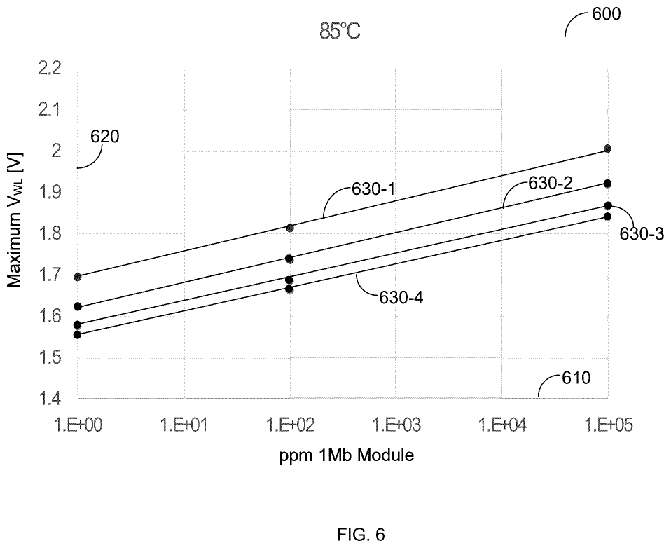

FIG. 6 is an example graph 600 depicting time-dependent dielectric breakdown (TDDB) gains according to an embodiment. The horizontal axis 610 of the graph depicts a part per million (ppm) value, where a lower ppm should be understood as being better. The ppm is measured as parts failing as a result of TDDM. The vertical axis 620 of the graph depicts the maximum word line voltage used for RESET programming. Four graphs, 630-1, 630-2, 630-3, and 630-4 are shown. In this case, the graphs 630-1 through 630-4 are generated for a 1 Mb array at 85° C. Graph 630-1 corresponds to 10,000 cycles at 100 nS. Graph 630-2 corresponds to 10,000 cycles at 1 μS. Graph 630-1 corresponds to 10,000 cycles at 100 nS×1024/22. Graph 630-4 corresponds to 100,000 cycles at 1 μS. It is clear from all graphs that lowering the word line voltage is advantageous. Consider the impact on ppm shown by graph 630-1. There is an improvement by three orders of magnitude when using a 1.8V word line voltage versus a 2V word line voltage. This provides significant module reliability improvement by leveraging TDDB reduction, as the number of cells impacted from overstress is reduced significantly. For example, in the programmed word line WLₘ 530-m, while all the transistors of the column m experience the 1.8V, the transistor experiences less stress than when applying 2V, and the implications are presented on the graph 600 for various cases.

In order to perform the teaching herein, the BL/SL control 120 and WL control 130 are modified to allow the application of the voltage scheme discussed herein. That is, BL/SL control 120 is modified to provide negative BL voltages as well as 0V. The BL/SL control 120 is further modified to provide a reduced SL voltage at programming, for example, 1.55V instead of 1.8V as provided by the current implementation. The WL control 130 is modified to provide a reduced WL voltage at programming, for example, instead of the typical 2V provided by the current implementation, providing 1.8V, and further modified to provide a negative voltage, for example, −0.25V, instead of 0V. It should be understood that these specific voltages are provided as examples and should not be limiting upon the scope of the disclosed embodiments. The negative voltages provided as shown herein, allows the reduction of the WL voltage at programming, hence exposing the transistors that are not being programmed to less stress, which results in an improved TDDB.

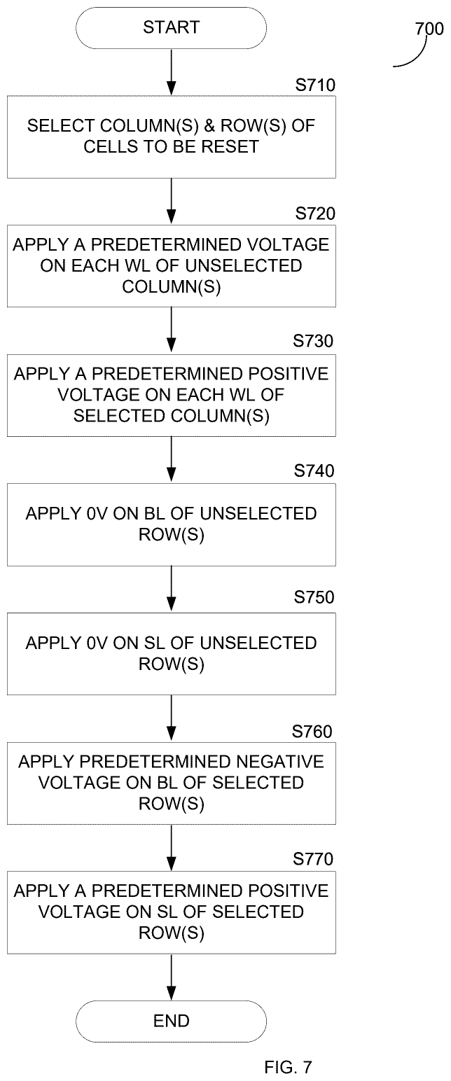

FIG. 7 is an example flowchart 700 describing RESET programming of a ReRAM array according to an embodiment. At S710, one or more columns and one or more rows of cells to be RESET are selected. Such a selection may be performed by, for example, a control logic 140 shown in FIG. 1, with modified BL/SL control 120 and modified WL control 130 as discussed herein. A selected row or column has at least one ReRAM cell to be RESET included therein. A non-selected row or column has no ReRAM cell to be RESET included therein.

At S720, a predetermined voltage, for example 0V, is applied to each WL of non-selected columns, i.e., the columns not selected at S710.

At S730, a predetermined positive voltage, for example 1.8V, is applied to each WL of selected columns, i.e., the columns selected at S710.

At S740, a reference voltage of 0V, or ground, is applied to the bit lines of non-selected rows.

At S750, a reference voltage of 0V, or ground, is applied to each SL of non-selected rows.

At S760, a predetermined negative voltage, for example-0.25V, is applied on BL of the one or more selected rows.

At S770, a predetermined positive voltage, for example 1.55V, is applied on SL of the one or more selected rows.

While S720 through S770 are described sequentially, the order should not be construed as being limited, and any other order of execution is possible. This further includes the application of the various voltages also in parallel for all or some of S720 through S770.

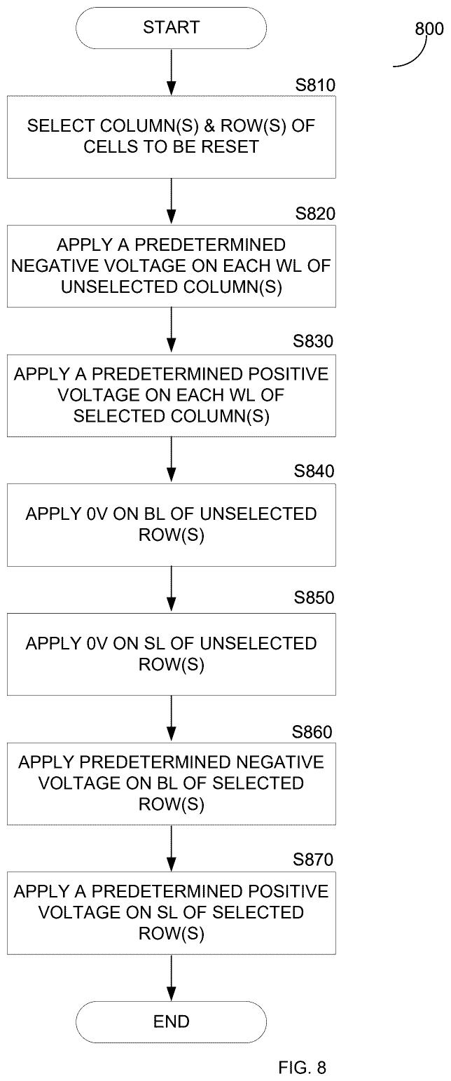

FIG. 8 is an example flowchart 800 describing RESET programming of a ReRAM array according to another embodiment. Specifically, in this embodiment, a negative voltage is applied also on each of the unselected WL. This is used when the biasing has reached a point where leakage becomes a problem, and therefore additional compensation is necessary to limit such leakage to within desired limits.

At S810, one or more columns and one or more rows of cells to be RESET are selected. Such a selection may be performed by, for example, a control logic 140 shown in FIG. 1, with modified BL/SL control 120 and modified WL control 130 as discussed herein. A selected row or column has at least one ReRAM cell to be RESET included therein. A non-selected row or column has no ReRAM cell to be RESET included therein.

At S820, a predetermined voltage, for example 0V, is applied to each WL of non-selected columns, i.e., the columns not selected at S710.

At S830, a predetermined positive voltage, for example 1.8V, is applied to each WL of selected columns, i.e., the columns selected at S710.

At S840, a reference voltage of 0V, or ground, is applied to the bit lines of non-selected rows.

At S850, a reference voltage of 0V, or ground, is applied to each SL of non-selected rows.

At S860, a predetermined negative voltage, for example-0.25V, is applied on BL of the one or more selected rows.

At S870, a predetermined positive voltage, for example 1.55V, is applied on SL of the one or more selected rows.

While S820 through S870 are described sequentially, the order should not be construed as being limited, and any other order of execution is possible. This further includes the application of the various voltages also in parallel for all or some of S820 through S870.

While specific example voltages are provided, it should be understood that ranges of voltages properly adjusted may be used, so long as for both WL voltages and BL voltages, a negative voltage is used according to the embodiments described herein. Hence, the first predetermined positive voltage may have a range of 1.5V to 1.8V in an embodiment. The second predetermined positive voltage may have a range of 0.85V to 0.95V in an embodiment. The first predetermined negative voltage may have a range of-400 mV to-100 mV. The second predetermined negative voltage may have a range of-400 mV to-100 mV.

All examples and conditional language recited herein are intended for pedagogical purposes to aid the reader in understanding the principles of the disclosed embodiment and the concepts contributed by the inventor to furthering the art and are to be construed as being without limitation to such specifically recited examples and conditions. Moreover, all statements herein reciting principles, aspects, and embodiments of the disclosed embodiments, as well as specific examples thereof, are intended to encompass both structural and functional equivalents thereof. Additionally, it is intended that such equivalents include both currently implemented equivalents as well as equivalents developed in the future, i.e., any elements developed that perform the same function, regardless of structure.

It should be understood that any reference to an element herein using a designation such as “first,” “second,” and so forth does not generally limit the quantity or order of those elements. Rather, these designations are generally used herein as a convenient method of distinguishing between two or more elements or instances of an element. Thus, a reference to first and second elements does not mean that only two elements may be employed there or that the first element must precede the second element in some manner. Also, unless stated otherwise, a set of elements comprises one or more elements.

As used herein, the phrase “at least one of” followed by a listing of items means that any of the listed items can be utilized individually, or any combination of two or more of the listed items can be utilized. For example, if a system is described as including “at least one of A, B, and C,” the system can include A alone; B alone; C alone; 2A; 2B; 2C; 3A; A and B in combination; B and C in combination; A and C in combination; A, B, and C in combination; 2A and C in combination; A, 3B, and 2C in combination; and the like.

What is claimed is:

1. A resistive random-access memory (ReRAM) device having improved time-dependent dielectric breakdown (TDDB) characteristic, comprising:
an array of ReRAM cells arranged in a plurality of columns and a plurality of rows, each cell comprising a resistive element having a first port and a second port and a select transistor having a gate port, a drain port and a source port, wherein the second port of the resistive element is electrically connected to the drain port of the select transistor;
a plurality of word lines, each word line designated to a column of the plurality of columns and electrically connecting to each gate of a select transistor of each ReRAM cell of the column;
a plurality of bit lines, each bit line designated to a row of the plurality of rows and electrically connecting to a first port of each resistive element of each ReRAM cell of the row;
a plurality of source lines, each source line designated to the row of the plurality of rows and electrically connecting to a source port of each select transistor of each ReRAM cell of the row;
a word line control unit (WLCU) electrically connect to each of the plurality of word lines;
a bit line and source line control (BLSLCU) unit electrically connected to each of the plurality of bit lines and each of the plurality of source lines; and
a control unit electrically connected to the BLSLCU and configured to provide a first negative voltage to a bit line of the plurality of rows at a RESET programming of a first ReRAM cell which includes the first ReRAM cell.

2. The ReRAM device of claim 1, wherein a word line voltage, at the RESET programming, is in a range between 1.5V and 1.8V.

3. The ReRAM device of claim 1, wherein the first negative voltage applied by the WLCU is between −400 mV and −100 mV.

4. The ReRAM device of claim 3, wherein the first negative voltage is −250 mV.

5. The ReRAM device of claim 1, wherein the control unit is further electrically connected to the WLCU and configured to provide a second negative voltage to a word line of the plurality of columns at RESET programming of a first ReRAM cell which do not include the first ReRAM cell.

6. The ReRAM device of claim 5, wherein the second negative voltage, applied by the BLSLCU, is between −400 mV and −100 mV.

7. The ReRAM device of claim 6, wherein the second negative voltage is −250 mV.

8. The ReRAM device of claim 1, wherein a select voltage applied by the BLSLCU to the each source line of non-selected rows is 0V.

9. The ReRAM device of claim 1, wherein a select voltage applied by the BLSLCU to the each source line of selected rows is between 1.55V and 1.8V.

10. The ReRAM device of claim 9, wherein the select voltage applied by the BLSLCU to the each source line of selected rows is 1.55V.

11. The ReRAM device of claim 1, wherein all unselected access transistors of a bit line of the plurality of bit lines have a total leakage current that is lower than a predetermined fraction of a current of the select transistor of the bit line.

12. The ReRAM device of claim 11, wherein the predetermined fraction is equal to or lower than 1%.

13. A method for performing a RESET programming of a resistive random-access memory (ReRAM) device having improved time-dependent dielectric breakdown (TDDB) characteristic, the method comprising:
selecting, by a bit line and source line control unit (BLSLCU) of the ReRAM device, one or more rows and, by a word line control unit (WLCU) of the ReRAM device, one or more columns of a ReRAM array of the ReRAM device, where intersecting selected columns and selected rows indicate that a ReRAM cell to be RESET, and wherein the indicated ReRAM cell is a selected ReRAM cell;
applying, by the WLCU, a first voltage to each word line of the ReRAM array of non-selected columns;
applying, by the WLCU, a first positive voltage to each word line of the ReRAM array of the selected columns;
applying, by the BLSLCU, a reference voltage to bit lines of non-selected rows;
applying, by the BLSLCU, a reference voltage to source lines of the non-selected rows;
applying, by the BLSLCU, a second negative voltage to bit lines of the selected rows; and
applying, by the BLSLCU, a second positive voltage to source lines of the selected rows;
wherein applying of the voltages cause the RESET of each of the selected ReRAM cells without overstressing select transistors of non-selected ReRAM cells.

14. The method of claim 13, wherein word line voltage, at the RESET programming, is in a range between 1.5V and 1.8V.

15. The method of claim 13, wherein the first voltage applied by the WLCU is a negative voltage.

16. The method of claim 15, wherein the first voltage is between −400 mV and −100 mV.

17. The method of claim 13, wherein the second negative voltage applied by the BLSLCU is between −400 mV and −100 mV.

18. The method of claim 13, wherein the reference voltage to the bit lines and the reference voltage to the source lines, applied by the BLSLCU, are 0V.

19. The method of claim 13, wherein the second positive voltage, applied by the BLSLCU to each source line of selected rows, is between 1.55V and 1.8V.

20. The method of claim 13, wherein voltages applied by WLCU are applied in parallel, wherein the voltages applied by the WLCU are any one of: the first voltage to each word line of the ReRAM array of the non-selected columns and the first positive voltage to each word line of the ReRAM array of the selected columns.

21. The method of claim 13, wherein voltages applied by BLSLCU are applied in parallel, wherein the voltages applied by the BLSLCU are any one of: the reference voltage to the bit lines of the non-selected rows, the reference voltage to the source lines of the non-selected rows, the second negative voltage to the bit lines of the selected rows, and the second positive voltage to the source lines of the selected rows.

22. The method of claim 13, wherein all unselected transistors of a bit line of the ReRAM device have a total leakage current that is lower than a predetermined fraction of a current of the select transistor of the bit line.

23. The method of claim 22, wherein the predetermined fraction is equal to or lower than 1%.
